(19) United States
(12) Patent Application Publication
(10) Pub. No.: US 2007/0298551 A1
(43) Pub. Date: Dec. 27, 2007

(54) Fabrication of silicon nano wires and gate-all-around MOS devices

(75) Inventors: Didier Bouvet, Morges (CH); Kirsten Moselund, Lausanne (CH); Mihai Adrian Ionescu, Ecublens (CH)

Correspondence Address: NIXON & VANDERHYE, PC, 901 NORTH GLEBE ROAD, 11TH FLOOR, ARLINGTON, VA, 22203, US

(73) Assignee: Ecole Polytechnique Federale De Lausanne (EPFL), Lausanne (CH)

(21) Appl. No.: 11/705,036

(22) Filed: Feb. 12, 2007

(30) Foreign Application Priority Data
Feb. 10, 2006 (IB) PCT/IB06/50448

(51) Int. Cl. H01L 21/336; C23F 1/00

(52) U.S. Cl. 438/151; 216/2; 438/284; 257/E21.409

(57) ABSTRACT

The invention relates to methods for manufacturing semiconductor devices. Processes are disclosed for implementing suspended single crystal silicon nano wires (NWs) using a combination of anisotropic and isotropic etches and spacer creation for sidewall protection. The core dimensions of the NWs are adjustable with the integration sequences: they can be triangular, rectangular, quasi-circular, or an alternative polygonal shape. Depending on the length of the NWs, going from the sub-micron to millimeter range, the NWs may utilize support from anchors to the side, during certain processing steps. By changing the lithographic dimensions of the anchors compared to the NWs, the anchors may be reduced or eliminated during processing. The method covers, among other things, the integration of Gate-All-Around NW (GAA-NW) MOSFETs on a bulk semiconductor. The GAA structure may consist of a silicon core fabricated as specified in the invention, surrounded by any usable gate dielectric, and finally by a gate material, such as polysilicon or metal. The source and drain of the GAA-NW may be connected to the bulk semiconductor to avoid self heating of the device over a wide range of operating conditions. The GAA-NW MOS capacitor can also be used for the integration of a Gate-All-Around optical phase modulator (GAA modulator). The working principle for the optical modulator is modulation of the refractive index by free carrier accumulation or inversion in a MOS capacitive structure, which changes the phase of the propagating light.

### TECHNICAL FIELD

The invention relates to the fabrication of silicon nano wires and gate-all-around MOS devices, for example, using spacers and a combination of anisotropic and isotropic etching and oxidation.

### BACKGROUND AND SUMMARY OF THE INVENTION

Nano wires (NWs) in many different materials are finding widespread applications. In some cases, they display unique physical properties not found in the bulk material (e.g., carbon nanotubes), and, in some applications, the dimensional control is used to enhance quantum effects (e.g., single electron transistors). Even for devices not exploiting the nanoscale effects, NW-based devices can offer compactness and superior performance, as compared to bulk or planar structures.

Silicon NWs are used today for multiple gate transistors as well as for waveguides for optical integrated circuits on silicon-on-insulator (SOI) wafers. In the latter case, the buried insulating dielectric, with refractive index less than that of silicon, is required for confinement of the light. Therefore, the fabrication of single crystal silicon waveguides generally requires the use of expensive SOI wafers as the starting material. This invention presents, among other things, a way of producing high quality single crystal waveguides in an arbitrary layout on a bulk silicon wafer.

Photonic waveguides is a fundamental building block for photonic integrated circuits, where they can carry optical signals just as it is the case for optical fibers, which use light to transmit data at the speed of light over very long distances. Apart from waveguiding, a photonic circuit also requires other functional blocks, such as a light emitter and detector, and a light modulator. The latter can also be implemented in this invention, by wrapping a section of the waveguide in a gate dielectric and gate material. Free carriers can then be induced in the NW channel by the capacitive operation of the gate. A mechanism for removing the charge from the channel again must be implemented to assure high speed modulation. This can be done in terms of source/drain connections.

For electronic devices, multiple gate transistors are generally more scalable than single gate transistors, since they offer reduced short channel effects, no body effect and reduced drain-induced barrier lowering (DIBL). The superior performance is due to a better screening of the electric field from the drain. Furthermore, multiple channels can produce more current than just a single channel.

In the existing technologies used for creating multiple gate devices, such as FINFET or Silicon-On-Nothing, the dimensions of the channel wire are determined by the physical thickness of the silicon layer and the lithography. In this invention, however, arbitrary cross sections, i.e. triangular, rectangular or quasi-circular, can be obtained, by varying the etching and oxidation steps. Similarly, there is no particular constraint on dimensions, which can vary from microns to nanometers. Nanometer-scale devices can be obtained by using standard lithography. Furthermore, the use of a bulk substrate means that ordinary planar transistors or other types of devices can be fabricated in the same process, by shielding these zones during the fabrication of the NW.

Single-crystal silicon waveguides: Single-crystal waveguides used for photonic integrated circuits are generally produced by etching of the top silicon layer of a SOI substrate possibly followed by an oxidation step to reduce the surface roughness. See, e.g., T. Tsuchizawa et al., “Microphotonics Devices Based on Silicon Microfabrication Technology,” J. Select. Topics Quantum Electron., Vol. 11, No. 1, pp. 232-240, 2005, which is incorporated herein by reference. In this approach, the vertical dimension of the waveguide is limited by the top silicon layer and a dielectric thickness of at least around 1 um, which is required for optical isolation, and the horizontal dimensions are determined by the lithographic resolution.

Multiple gate devices: One of the most applied technologies today are FINFET. See, e.g., D. M. fried et al., “Improved independent gate N-type FinFET fabrication and characterization,” Elctron Dev. Lett., Vol. 24, No. 9, pp. 592-594, 2003, which is incorporated herein by reference. In this process, a so-called thin vertical “fin” is etched on a SOI wafer spanned between a source and drain plot and generally presenting an aspect ratio greater than one, an oxidation is used to further reduce dimensions. A gate oxide is created and one or more “fins” are covered by the gate material. This results in a triple-gate structure, where the two horizontal gates are much larger than the top vertical gate.

Another widely used technology is to create a flat silicon bridge by first epitaxial growth of SiGe followed by a thin silicon layer, and then subsequent selective etching of the SiGe layer. See, e.g., S. Monfray et al., “50 nm—Gate all around (GAA)—Silicon on nothing (SON)—Devices: A simple way to co-integration of GAA transistors within bulk MOSFET process,” Tech. Digest, IEEE Symp. VLSI Circuits, pp. 108-109, 2002, which is incorporated herein by reference; and S. Harrison et al., “Highly Performant Double Gate MOSFET realized with SON process,” Tech. Digest, Int. Electron Devices Meeting, pp. 449-452, 2003, which is incorporated herein by reference. This creates basically a double gate-like structure, since the influence of the two vertical gates is negligible compared to the two horizontal gates. In this case, the thickness of the silicon channel as well as the underlying dielectric, which is determined by the SiGe thickness, can be tailored individually. However, this process requires the use of an advanced epitaxial process, and the isolating buried dielectric thickness, will in reality be limited by the ability to grow a good quality thick SiGe-film, with sufficiently high germanium concentration to allow for selective etching. This is not prohibitive for electronics, but, for photonic purposes, a minimum dielectric thickness of about 1 um is required, to prevent coupling to the substrate.

This invention concerns a novel way of fabricating single-crystal silicon NWs of arbitrary cross section. The NWs can find applications both as GAA MOS transistors, as photonic waveguides and as the core of an optical phase modulator based on a GAA MOS capacitor.

The NWs are produced by using a hard mask of a dielectric material to etch a rib in the silicon surface. The sides of the rib are then protected by spacers consisting of one or more dielectric layers. The spacers protect the NW during the subsequent isotropic etching step. The isotropic etching step has two purposes: (i) the vertical etching defines the distance from the bottom of the NW to the substrate, which can be important for optical isolation, and (ii) the horizontal component serves to liberate the NW, either directly by etching or in the subsequent oxidation steps. One or more oxidations are carried out, with or without the hardmask, to obtain the desired shape and dimension of the NW, and also to improve the quality of the surface, which might have been damaged by the dry-etching step.

### BRIEF DESCRIPTION OF THE DRAWINGS

The left column of the drawings describes an exemplary process flow for a GAA MOSFET, whereas the right column of the drawings describes an exemplary process flow for an optical GAA phase modulator and accompanying optical waveguide. The process flows are basically the same, but the individual steps are optimized differently depending on the desired shape and dimension of the NW, which differs in the two cases. For example, there is a lower boundary for the dimensions of a photonic waveguide, given by light confinement as well as optical losses, whereas the same is not the case for a GAA MOSFET.

FIG. 1a is a drawing illustrating the cross sections of an exemplary semiconductor device, showing the silicon wafer [100], covered by a hard mask which may consist of one or more dielectric layers, and on top the patterned resist layer [110], whose design will be transferred into the silicon.

FIG. 1b is a diagram illustrating a top view of a silicon NW structure formed on the semiconductor device shown in FIG. 1a. In the case of the optical device, it shows both the passive waveguide as well as an optical modulator structure.

FIG. 2 is a drawing illustrating a cross section along the line AA′ in the FIG. 1b showing the spacer formation.

FIG. 3 is a drawing illustrating a cross section along the line AA′ showing the silicon nano wire pre-formation.

FIG. 4 is a drawing illustrating a cross section along the line AA′ showing the silicon nano wire formation.

FIG. 5 is a drawing illustrating a cross section along the line AA′ showing the silicon nano wire release.

FIG. 6 is a drawing illustrating a cross section along the line AA′ showing the silicon nano wire surrounded by LTO.

FIG. 7 is a drawing illustrating schematically a cross section along the line AA′ showing the silicon NW surrounded by the gate material layer. In the case of optical structures, the passive waveguide might be kept embedded in the LTO (Low Thermal Oxide), whereas the modulator region must be opened to allow for gate dielectric and gate formation.

FIG. 8 is a diagram schematically illustrating a top view of the patterned and etched gate structure surrounding the silicon nano wire structure as shown in the FIG. 7.

FIG. 9 is a drawing illustrating schematically a cross section along the line AA′ of the gate materials layers over the silicon nano wire patterned according to the FIG. 8 and covered with a dielectric layer.

FIG. 10 is a drawing illustrating schematically a cross section along the line BB′ of source and drain contacts formation.

### DETAILED DESCRIPTION

The following detailed description of the subject matter refers to the accompanying drawings. The same reference numbers may be used in different drawings to identify the same or similar elements. The drawings on the left pertain to an exemplary embodiment of the invention as a GAA MOSFET, which will be described first, whereas the drawings on the right describe an exemplary embodiment of the invention as a photonic waveguide, and an optical modulator.

FIG. 1a illustrates the cross section of a semiconductor device 100 formed in accordance with an embodiment of the present invention. Referring to FIG. 1, the semiconductor device 100 will most likely be a bulk silicon wafer, but there is nothing that hinders the use of thick SOI, SiGe or alternative technologies. A dielectric layer 101 such as silicon oxide (e.g., SiO₂) may be formed over the semiconductor device 100 and then covered with a second dielectric layer 102 such as silicon nitride (Si₃N₄). Silicon nitride layer acts as a protective layer during subsequent etching processes whereas silicon oxide is used to prevent silicon stressing. However, a single dielectric material can also be used in which case 101 and 102 would be identical.

In an exemplary implementation, the silicon oxide layer 101 may be grown to have a thickness ranging from 100 to 1000 A. Then, the silicon nitride layer 102 ranging from 100 to 1000 A may be deposited. Then, a photo sensitive material 110 may be deposited, patterned and developed in any conventional manner. The silicon oxide layer 101 and silicon nitride layer 102 are etched in conventional manner, in order to transfer the resist pattern. Then, a semiconductor device 100 is etched to form simultaneously the NW structure 104 and the source and drain areas 204. In an exemplary implementation, the semiconductor device 100 is bulk silicon and the trench depth in the bulk silicon is 0.5 μm. The trench depth may range to about 0.1 to 3.0 μm.

FIG. 1b illustrates the top view of a NW structure 104, with source and drain regions 204 on the semiconductor device 100 formed in such a manner.

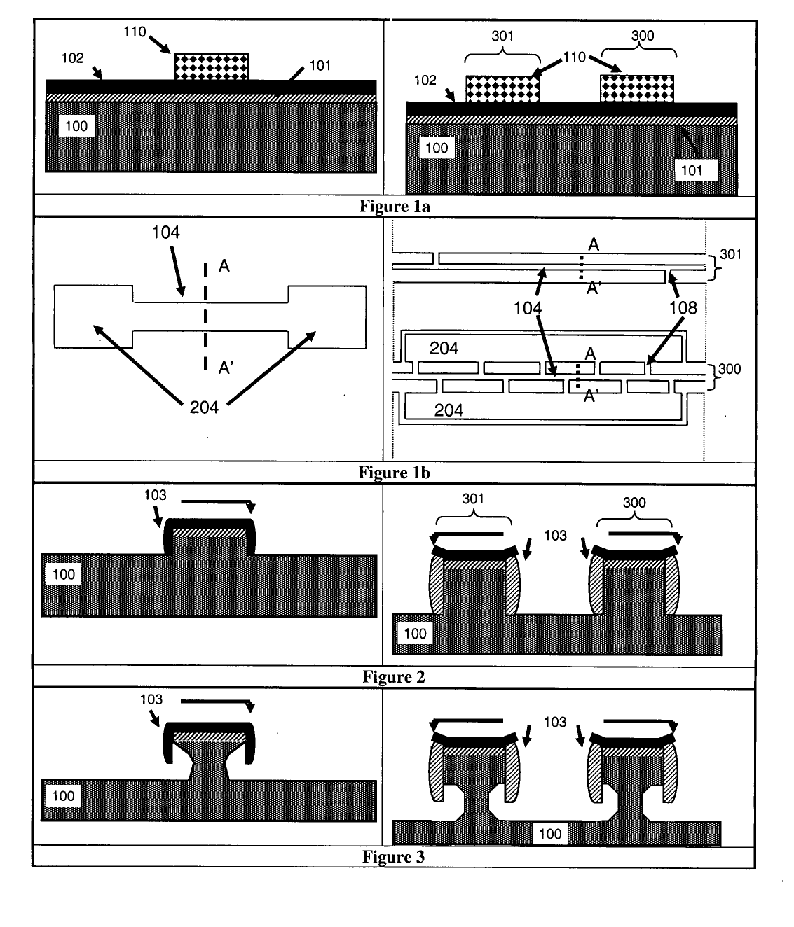

FIG. 2 is a cross section along the line AA′ in the FIG. 1b illustrating the formation of the spacers 103. In an exemplary implementation, the spacer 103 is formed with a silicon nitride with a thickness ranging from 50 to 800 A. The spacers 103 may be also formed with a silicon dioxide (e.g., SiO₂) with a thickness ranging from 100 to 3000 A. The spacer 103 is formed in a conventional manner. The spacer 103 is used as a protective layer of the side surface of the NW 104 during the subsequent isotropic etching processes.

FIG. 3 is a cross section along the line AA′ in the FIG. 1b illustrating the pre-formation of the NW structure 104 with an isotropic etching of the semiconductor device 100. In an exemplary implementation, the bottom part of NW 104 is still connected to the semiconductor device 100 with a link width ranging from about 0.05 to 0.5 μm. Source and drain regions 204 are also connected to the semiconductor device 100. In other implementations, the NW 104 may be disconnected from the semiconductor device after the isotropic etching, so that the link width is zero.

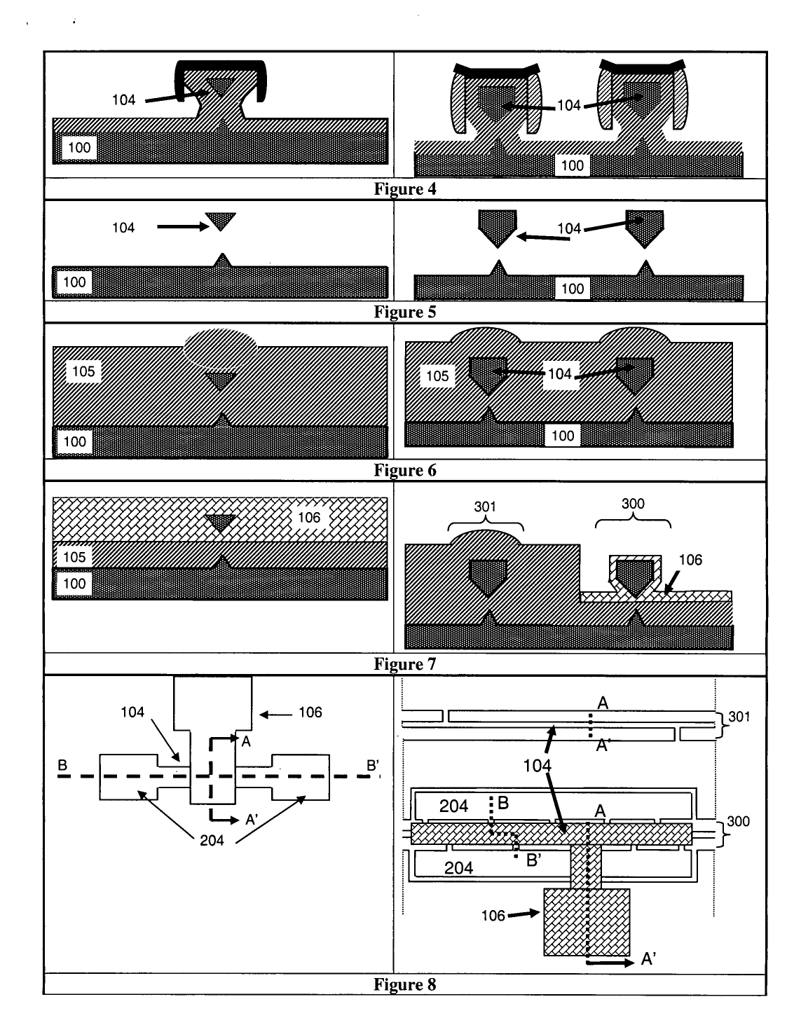

FIG. 4 is a cross section along the line AA′ in the FIG. 1b illustrating the formation of the NW 104 after the oxidation in a conventional manner of the semiconductor device 100. In an exemplary implementation, the oxide thickness ranges from about 0.1 to 1.0 μm depending on the link width. Source and drain regions 204 are connected to the semiconductor device 100.

FIG. 5 is a cross section along the line AA′ in the FIG. 1b illustrating the NW 104 release in a conventional manner. In an exemplary implementation, the core of the silicon NW 104 is triangular; its diameter ranges from about 20 to 500 nm. In other implementations, its diameter may be rectangular, pentagonal or quasi-circular with similar dimensions.

FIG. 6 is a cross section along the line AA′ in the FIG. 1b illustrating the NW surrounded by a dielectric layer 105 (e.g., SiO₂, polyimide, low k . . . ) deposited in a conventional manner. In an exemplary implementation, the dielectric layer 105 is LTO (Low Thermal Oxide). The dielectric layer 105 thickness or its equivalent has to be thick enough to be planarized by CMP before reaching the NW with slurry composed of fumed silica particles or colloidal silica particles or alumina particles or cerium oxide particles, at pH basic, neutral or acid.

FIG. 7 is a cross section along the line AA′ in the FIG. 1b illustrating the second release of the NW 104 followed by the deposition of gate oxide (not displayed in the drawing) or equivalent dielectric and gate materials layers 106 including amorphous silicon, polysilicon or metallic layers. The etching (second release) has to be isotropic in order to release the bottom part of the NW, a wet etching method might be desirable in order not to damage the surface. The gap between the bottom part of the NW 104 and the remaining silicon dioxide or its equivalent 105 has to be large enough to allow the formation of the gate oxide and the gate materials layers 106 around the NW. In an exemplary implementation, the gap ranges from about 0.3 to 0.6 82 m.

FIG. 8 illustrates the top view of the exemplary gate material layer patterning on the NW 104 with source and drain regions 204 on the exemplary semiconductor device 100 formed in such a manner. Gate material layers 106 (concerned ones) and source/drain regions 204 may be implanted to respond to the state of the art circuit requirements for such electronic devices (not shown). Specific annealing steps may be introduced for this purpose.

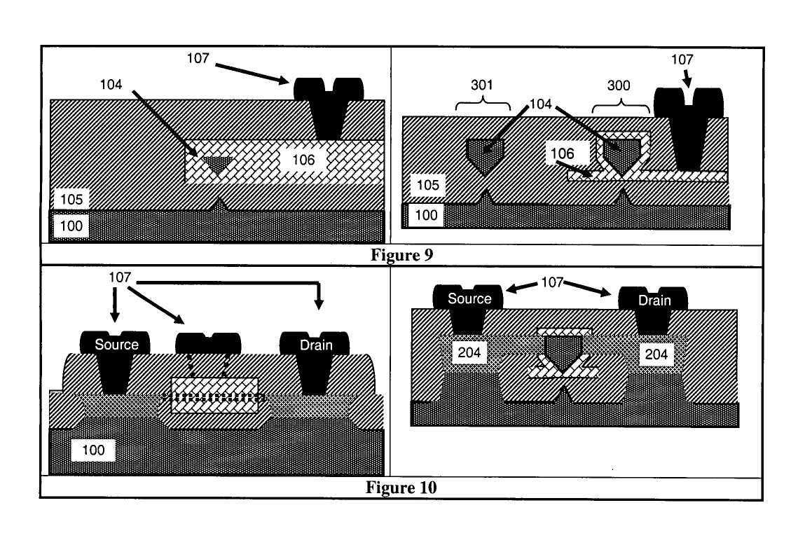

FIG. 9 is a cross section along the line AA′ in the FIG. 8 illustrating the interlayer dielectric layer (ILD) 105 and a gate contact filled with a metal 107. Conventional architectures and processes for contact and metallization may be employed. In an exemplary implementation, metal 107 is AlSi 1%.

FIG. 10 is a cross section along the line BB′ in the FIG. 8 illustrating the interlayer dielectric layer (ILD) 105 and source and drain contacts filled with a metal 107. In an exemplary implementation, metal 107 is AlSi 1%.

The following describes some exemplary alternative implementations of opto electronic modulators and passive waveguides. In the following, alternative implementations of the invention, for fabrication of optical waveguides 301, and an optoelectronic phase modulator 300 based on charge injection in a MOS capacitive structure, are described.

The processing steps are mainly the same as those used for the implementation of the GAA MOSFET, but the exemplary differences will be highlighted in the following. The following description refers to the right column of FIGS. 1 through 10.

FIG. 1a: The first lithographic step illustrated in FIG. 1a, is similar for the two processes, the only difference may be in the thickness of the dielectric layer 102 and in the design.

A dielectric layer 101 such as silicon oxide (e.g., SiO₂) may be formed over the semiconductor device 100 and then covered with a dielectric layer 102 different than 101 such as silicon nitride (Si₃N₄). Silicon nitride layer acts as a protective layer during subsequent etching and oxidation processes, whereas silicon oxide is used to prevent silicon stressing. In an exemplary implementation, the silicon oxide layer 101 may be grown to have a thickness ranging from 100 to 1000 A. Then, the silicon nitride layer 102 ranging from 100 to 3000 A may be deposited. Then, a photo sensitive material may be deposited, patterned and developed in any conventional manner.

The combination of layers 101 and 102 serves as a hard mask. They are etched in any conventional manner, where care is taken to assure a smooth profile, in order not to increase the optical losses. The semiconductor device 100 is etched to form simultaneously the NW structure 104 and the source and drain areas 204. The anchors 108 are required as support for the suspended NW in the waveguide 301, whereas for the optical modulator 300 they serve the double purpose of mechanical support and source/drain connection. Therefore, the frequency and dimensions for the two application 300 and 301, may require a different anchor design 108, which could be rectangular, triangular or any other fitting shape.

For the waveguide 301, mechanical stability will determine the frequency of anchors 108, which could possibly be spaced 50-500 um. For the optical modulator 300, the speed of the device depends on the channel length, i.e., the distance between anchors 108, thus for this structure the spacing could potentially lie in the range 1-100 um.

For the waveguide 301, the anchors 108 are only required during processing, until the NW 104 is encapsulated in the ILD 105, therefore the design of the anchors may be such, that they will disappear completely or partly during the preceding oxidation steps.

FIG. 1b illustrates the top view of a NW structure 104 used for two different implementations, 301 as a passive waveguide, and with an optical modulator 300 inserted, in this case source and drain regions 204 must be defined to supply and evacuate the free carriers from the channel region.

FIG. 2 is a cross section along the two paths AA′ in the FIG. 1b illustrating the formation of the spacers 103. In an exemplary implementation, the spacer 103 is formed by oxidation, which simultaneously reduces the horizontal dimensions, but any other combination of one or several materials which etch selectively to silicon may be used, the thickness ranges from 50 to 5000 A. The spacer 103 is used as a protective layer of the side surface of the NW 104 during the subsequent isotropic etching processes.

FIG. 3 shows the same cross section as FIG. 2, illustrating the pre-formation of the NW structure 104 with an isotropic etching of the semiconductor device 100. In the exemplary implementation shown here, the bottom part of NW 104 is still connected to the semiconductor device 100 with a link width ranging from about 0.05 to 0.5 μm. However, depending on design and previous processing this may not be the case, but the anchors 108, will maintain the suspended waveguide if this is completely under etched at this point. Source and drain regions 204 are also connected to the semiconductor device 100.

FIG. 4 illustrates the formation of the NW 104 after the oxidation in a conventional manner of the semiconductor device 100. In an exemplary implementation, the oxide thickness ranges from about 0.1 to 1.0 μm depending on the link width. Source and drain regions 204 as well as anchors 108 are also connected to the semiconductor device 100, though this is not shown in this cross section.

FIG. 5 is a cross section along the two lines AA′ in the FIG. 1b illustrating the NW 104 release in a conventional manner. In an exemplary implementation, the core of the silicon NW 104 is pentagonal, but depending on the duration of etching and oxidation steps it tends towards a triangular shape. Its diameter ranges from about 20 to 500 nm. In other implementations, the cross section of the nano wire may be rectangular or quasi-circular with similar dimensions.

The illustration here shows a complete release of the NW 104 from the substrate 100, in another implementation, however, a narrow link might remain at this point. In this case, a second oxidation is required before the deposition of the ILD 105. Since the grown oxide has a refractive index less than that of silicon, it will serve as a cladding for the photonic waveguide, and there would be no need to remove this oxide before the deposition of the ILD 105.

FIG. 6 illustrates the NW surrounded by a dielectric layer 105 (e.g., SiO₂, polyimide, low k . . . ), deposited in a conventional manner, and having a refractive index smaller than that of silicon so as not to interfere with the waveguiding properties. In an exemplary implementation, the dielectric layer 105 is LTO (Low Thermal Oxide). The dielectric layer 105 thickness or its equivalent has to be thick enough to be planarized by CMP before reaching the NW with slurry composed of fumed silica particles or colloidal silica particles or alumina particles or cerium oxide particles, at pH basic, neutral or acid.

FIG. 7 illustrates the second release of the NW 104, in the example shown here only the NW 104, used for the implementation of the modulator 300, is released, whereas the passive waveguide 301 is kept encapsulated in the LTO. However, release of all waveguides is also possible, but this will require masking of the passive waveguide 301 during subsequent implantation steps. The etching (second release) has to be isotropic in order to release the bottom part of the NW, a wet etching method may prevent damage of the silicon surface. After having released the modulator section 300, the gate dielectric is grown or deposited in a conventional manner (not shown on the drawing). Then, the gate material 106 is deposited. In an example implementation, the gate material is either amorphous silicon or polysilicon. The gap between the bottom part of the NW 104 and the remaining silicon dioxide or its equivalent 105 has to be large enough to allow the formation of the gate oxide and the gate materials layers 106 around the NW, and to isolate the photonic waveguide 104 optically from the substrate 100 in order to avoid substrate leakage of the optical signal.

FIG. 8 illustrates the top view of the two implementations, the passive waveguide 301 which is not affected, and the optical modulator 300, with the gate material patterning design. Gate material layers 106 (concerned ones) and source/drain regions 204 may be implanted to respond to the state of the art circuit requirements for such electronic devices (not shown). Thus, they may be implanted with the same type of doping or with one being p-type and the other n-type, and they may be implanted as suitable for operation in either accumulation, inversion or sub-threshold. Any implantation may be followed by a suitable thermal activation step.

FIG. 9 is a cross section along the two lines AA′ in the FIG. 8 illustrating the NWs 104, which in the case of the modulator 300 is surrounded by the gate material, the interlayer dielectric layer (ILD) 105 and a gate contact filled with a metal 107. Conventional architectures and processes for contact and metallization may be employed.

FIG. 10 is a cross section along the line BB′ in the FIG. 8 illustrating the source and drain connections 204, which are connected at different points to the NW core, the interlayer dielectric layer (ILD) 105 and source and drain contacts filled with a metal 107.

Without prejudice to the principles of the invention, the details of construction and processing and the embodiments may vary widely with respect to what is described and illustrated herein purely by way of example, and without thereby departing from the scope of the invention.

What is claimed is:

1. A method of manufacturing a semiconductor device comprising:
1.1. creating a NW of semiconductor on a bulk semiconductor
1.2. creating a NW of semiconductor isolated from the bulk of the semiconductor
1.3. creating a NW of semiconductor formed from a bulk of the semiconductor
1.4. creating a NW of semiconductor connected to source and drain pads
1.5. creating source drain pads connected to the bulk of the semiconductor
1.6. creating a gate all around structure

2. The method of claim 1, carried out on an alternative substrate, such as SOI.

3. The method of claim 1, wherein the thickness of NW of semiconductor ranges from 1 nm to 500 nm.

4. The method of claim 1, wherein the distance between the NW of semiconductor and the bulk of semiconductor is higher than 10 nm.

5. The method of claim 1, wherein the thickness of the gate all around structure ranges from 5 nm to 1 μm.

6. The method of claim 5, wherein the gate all around structure is composed of a dielectric layer surrounded by a metallic layer or a doped semiconductor layer.

7. The method of claim 1, wherein the shape of the core of the NW of semiconductor results from a combination of isotropic etching and anisotropic etching steps.

8. The method of claim 1, wherein the shape of the core of the NW of semiconductor results of the protection of side and top surfaces of the NW of semiconductor with protective layers.

9. The method of claim 7, wherein the protective layers can be dielectric layers or photoresist layers or low k.

10. The method of claim 1, wherein the shape of the core of the NW of semiconductor can be triangular, rectangular, pentagonal, hexagonal, polygonal or quasi circular.

11. The method of claim 1, wherein the source and drain pads may be doped to be electrically active.

12. The method of claim 1, wherein the gate all around structure may be doped to be electrically active.

13. The method of claim 1, wherein the semiconductor device is a Gate-All-Around NW MOSFET (GAA-NW).

14. The method of claim 1, wherein the semiconductor device is Gate-All-Around optical phase modulator (GAA modulator).

15. A method of manufacturing a semiconductor waveguide comprising:
15.1. creating a NW of semiconductor on a bulk semiconductor
15.2. creating a NW of semiconductor isolated from the bulk of the semiconductor
15.3. creating a NW of semiconductor formed from a bulk of the semiconductor
15.4. creating a NW of semiconductor suitable for the propagation of optical signals

16. The method of claim 15, wherein the thickness of NW of semiconductor ranges from 50 nm to 2 μm.

17. The method of claim 15, wherein the distance between the NW of semiconductor and the bulk of semiconductor is greater than 500 nm.

18. The method of claim 15, wherein the NW may be surrounded by any dielectric, including air, having a refractive index less than that of the semiconductor.

19. The method of claim 15, wherein the shape of the core of the NW of semiconductor results from a combination of isotropic etching and anisotropic etching steps.

20. The method of claim 15, wherein the shape of the core of the NW of semiconductor results in the protection of side and top surfaces of the NW of semiconductor with protective layers.

21. The method of claim 20, wherein the protective layers can be dielectric layers or photoresist layers or low k, or a combination of these.

22. The method of claim 15, wherein the shape of the core of the NW of semiconductor can be triangular, rectangular, pentagonal, hexagonal or quasi circular.

23. The method of claim 15, wherein the semiconductor device is used for the propagation of optical signals.
